(19) United States
(12) Patent Application Publication
(10) Pub. No.: US 2024/0105718 A1
(43) Pub. Date: Mar. 28, 2024

(54) INTEGRATED CIRCUIT DEVICES WITH PROTECTION LINER BETWEEN DOPED SEMICONDUCTOR REGIONS

(71) Applicant: Intel Corporation, Santa Clara, CA (US)

(72) Inventors: Tao Chu, Portland, OR (US); Guowei Xu, Portland, OR (US); Minwoo Jang, Portland, OR (US); Yanbin Luo, Portland, OR (US); Feng Zhang, Hillsboro, OR (US); Ting-Hsiang Hung, Beaverton, OR (US); Chia-Ching Lin, Portland, OR (US)

(73) Assignee: Intel Corporation, Santa Clara, CA (US)

(21) Appl. No.: 17/934,251

(22) Filed: Sep. 22, 2022

(51) Int. Cl. H01L 27/088; H01L 21/8234; H01L 29/06; H01L 29/08; H01L 29/778; H01L 29/786

(52) U.S. Cl. CPC H01L 27/0886; H01L 21/823412; H01L 21/823418; H01L 29/0673; H01L 29/0847; H01L 29/778; H01L 29/78696

(57) ABSTRACT

Methods for fabricating an integrated circuit (IC) device with a protection liner between doped semiconductor regions are provided. An example IC device includes a channel material having a first face and a second face opposite the first face, a first doped region and a second doped region in the channel material, extending from the second face towards the first face by a first distance; and an insulator structure in a portion of the channel material between the first and second doped regions, the insulator structure extending from the second face towards the first face by a second distance greater than the first distance. The insulator structure includes a first portion between the second face and the first distance and a second portion between first distance and the second distance. The insulator structure includes a liner material on sidewalls of the first portion but absent on sidewalls of the second portion.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors may help with such an optimization.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a flow diagram of an example method of fabricating an integrated circuit (IC) device with a protection liner between doped semiconductor regions, in accordance with various embodiments of the present disclosure.

FIGS. 2-8 illustrate cross-sectional side views at various stages in the manufacture of an example IC structure according to the method of FIG. 1, in accordance with some embodiments, in accordance with various embodiments of the present disclosure.

FIG. 9 illustrates a cross-sectional side view of an example IC device with a protection liner between doped semiconductor regions, in accordance with some embodiments of the present disclosure.

FIG. 10 illustrates top views of a wafer and dies that include a protection liner between doped semiconductor regions in accordance with any of the embodiments of the present disclosure.

FIG. 11 is a cross-sectional side view of an IC package that may include one or more IC devices with a protection liner between doped semiconductor regions in accordance with any of the embodiments of the present disclosure.

FIG. 12 is a cross-sectional side view of an IC device assembly that may include one or more IC devices with a protection liner between doped semiconductor regions in accordance with any of the embodiments of the present disclosure.

FIG. 13 is a block diagram of an example computing device that may include one or more IC devices with a protection liner between doped semiconductor regions in accordance with any of the embodiments of the present disclosure.

FIG. 14 is a block diagram of an example radio frequency (RF) device that may include one or more IC devices with a protection liner between doped semiconductor regions in accordance with any of the embodiments of the present disclosure.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

The fabrication of IC devices may include various steps. In some instances, there may be a need to electrically isolate two doped semiconductor regions in a channel material as part of a fabrication process in forming an IC device. To that end, a portion of the channel material may be removed to create an opening between two doped semiconductor regions, for example, using any suitable etching techniques, and subsequently an insulating material may be used to fill the opening to provide electrical isolation between the doped semiconductor regions. Unfortunately, the etching can damage the surface of one or both of the doped semiconductor regions. For instance, etching can unintentionally remove a portion from the sidewalls of one or both of the doped semiconductor regions. The damage to the doped semiconductor region(s) can lower the performance of the device.

In the context of fabricating transistors, such as P-type metal-oxide-semiconductor (PMOS) transistors and/or N-type metal-oxide-semiconductor (NMOS) transistors, the doped semiconductor regions may correspond to the source and/or drain (S/D) regions of the transistors. In some examples, an IC device may have multiple transistors formed adjacent to one another, where the source region of one of a nearest-neighbor pair of transistors may be adjacent to the drain region of the other one of the nearest-neighbor pair of transistors. To electrically isolate the two neighboring transistors, a portion of the channel material between the source region of one of the nearest-neighbor pair of transistors and the drain region of the other one of the nearest-neighbor pair of transistors may be removed, for example, by etching. The etching can cause damage to the source region of the transistor and/or the drain region of the adjacent transistor. In some instances, the damage to the S/D regions can impact the threshold voltages of the transistors (e.g., V_{TN} in the case of a NMOS transistor or V_{TP} in the case of a PMOS transistor). The threshold voltage of an NMOS transistor or a PMOS transistor may refer to the minimum gate-to-source voltage that is needed to create a conducting path between the source and drain terminals of the transistor. Additionally or alternatively, the damage to the S/D regions can degrade the saturation current (ISSAT) of the transistors. The saturation current of a transistor may refer to the maximum amount of current that can flow through the transistor. Accordingly, damages to S/D regions of a transistor can impact the transistor performance.

To address the performance impact discussed above, the present disclosure provides techniques for fabricating IC devices with isolation between two doped semiconductor regions in a way that can avoid damage to the doped semiconductor regions. For example, the two doped semiconductor regions may extend into a portion of a channel material, and a portion of the channel material between the two doped semiconductor regions may be removed by performing etching in multiple steps and depositing a protection liner during the etching process. More specifically, the protection liner can be deposited between two etching steps or prior to an etching step that is likely to cause damage to the doped semiconductor regions.

According to embodiments of the present disclosure, an IC device may include a channel material having a first face and a second face, where the second face may be opposite to the first face. The IC device may further include a first doped region and a second doped region in the channel material. The first and second doped regions may include doped semiconductor materials. Each of the first and second doped regions may extend from the second face of the channel material towards the first face of the channel material. For example, at least one of the first or second doped regions may extend from the second face towards the first face by a first distance. The IC device may further include an insulator structure in a portion of the channel material between the first and second doped regions. The insulator structure may extend from the second face of the channel material towards the first face of the channel material by a second distance, where the second distance may be greater than the first distance. In some instances, the insulator structure can extend through the entire thickness of the channel material, and thus the second distance may correspond a distance between the first and second faces of the channel material. Further, the insulator structure may have a first portion and a second portion, where the first portion may be a portion of the insulator structure extending from the second face of the channel material to the first distance, and the second portion may be a portion of the insulator structure extending from the first distance to the second distance. The insulator structure may include a liner material on at least portions of sidewalls of the insulator structure in the first portion but may not be on at least portions of the sidewalls of the insulator structure in the second portion.

In some embodiments, the insulator structure may include an insulator material. The insulator material may be on a portion of a sidewall of the insulator structure that is closest to the first doped region, where the liner material is between the insulator material and the first doped region. The insulator material may also be on a portion of a sidewall of the insulator structure that is closest to the second doped region, where the liner material is between the insulator material and the second doped region. Further, on the portion of the sidewall of the insulator structure that is closest to the first doped region, the liner material may be in contact with the first doped region. In a similar way, on the portion of the sidewall of the insulator structure that is closest to the second doped region, the liner material may be in contact with the second doped region.

In some embodiments, the insulator material in at least a portion of the second portion of the insulator structure may be in contact with the channel material. In some embodiments, a width of a sub-portion (e.g., a first sub-portion) of the second portion of the insulator structure may be smaller than a width of another sub-portion (e.g., a second sub-portion) of the second portion of the insulator structure. The width of the first sub-portion and the width of the second sub-portion may be in a dimension measured in a direction substantially parallel to a support over which the IC device is provided. In some embodiments, an average width of the first portion of the insulator structure is greater than an average width of the second portion of the insulator structure.

In some embodiments, the liner material may be in a layer (e.g., a thin film) having a thickness between about 0.5 and 2.5 nanometers. In some embodiments, the liner material may be selective with respect to the channel material. In some embodiments, the liner material may include oxygen. In some embodiments, the channel material may have a shape of a fin. In general, the channel material may have any suitable shapes (e.g., in the shape of a plane, a nanoribbon, a nanowire, etc.).

In some embodiments, the IC device may further include a first transistor and a second transistor adjacent to the first transistor, where the first doped region may be a source region of the first transistor and the second doped region may be a drain region of the second transistor. In some embodiments, the IC device may have a third doped region and a fourth doped region in the channel material, where the first, second, third, and fourth doped regions may be spaced apart from each other, the first and second doped regions may be a nearest-neighbor pair of doped regions in the channel material, and at least a portion of the channel material channel material has a shape of a fin.

The present disclosure may use the terms “protection liner,” “liner,” “protection material,” and “liner material” interchangeably to refer to a strong, tough material (e.g., in a thin layer) that can protect doped semiconductor regions from damage during an etching process.

Each of the structures, packages, methods, devices, and systems of the present disclosure may have several innovative aspects, no single one of which being solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “sidewall” may refer to a surface that is designed to be perpendicular to a support structure (e.g., a die, a wafer, a substrate, a package substrate, or a carrier substrate) of the IC device but may not always end up being exactly perpendicular due to manufacturing processes used to fabricate IC devices. Therefore, as used herein, the term “sidewall” refers to a surface that extends away from a support structure of the IC device and that may be substantially perpendicular, within a certain tolerance. In another example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc. Similarly, the terms naming various compounds refer to materials having any combination of the individual elements within a compound (e.g., “gallium arsenide” or “GaAs” may refer to a material that includes Gallium and Arsenic). Further, the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value based on the context of a particular value as described herein or as known in the art.

The term “interconnect” may refer to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

The terms such as “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated.

In the drawings, some schematic illustrations of example structures of various structures, devices, and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC devices with a protection liner between doped semiconductor regions as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with a protection liner between doped semiconductor regions as described herein may be implemented in one or more components associated with an IC or/and between various such components. In various embodiments, components associated with an IC include, for example, transistors, diodes, power sources, resistors, capacitors, inductors, sensors, transceivers, transmitters, receivers, antennas, etc. Components associated with an IC may include those that are mounted on an IC, provided as an integral part of an IC, or those connected to an IC. The IC may be either analog or digital, or may include a combination of analog and digital circuitry, and may be used in a number of applications, such as microprocessors, optoelectronics, logic blocks, audio amplifiers, etc., depending on the components associated with the IC. In some embodiments, IC devices with a protection liner between doped semiconductor regions as described herein may be included in a RFIC, which may, e.g., be included in any component associated with an IC of an RF receiver, an RF transmitter, or an RF transceiver, or any other RF device, e.g., as used in telecommunications within base stations (BS) or user equipment (UE) devices. Such components may include, but are not limited to, power amplifiers, RF switches, RF filters (including arrays of RF filters, or RF filter banks), or impedance tuners. In some embodiments, the IC devices with a protection liner between doped semiconductor regions as described herein may be employed as part of a chipset for executing one or more related functions in a computer.

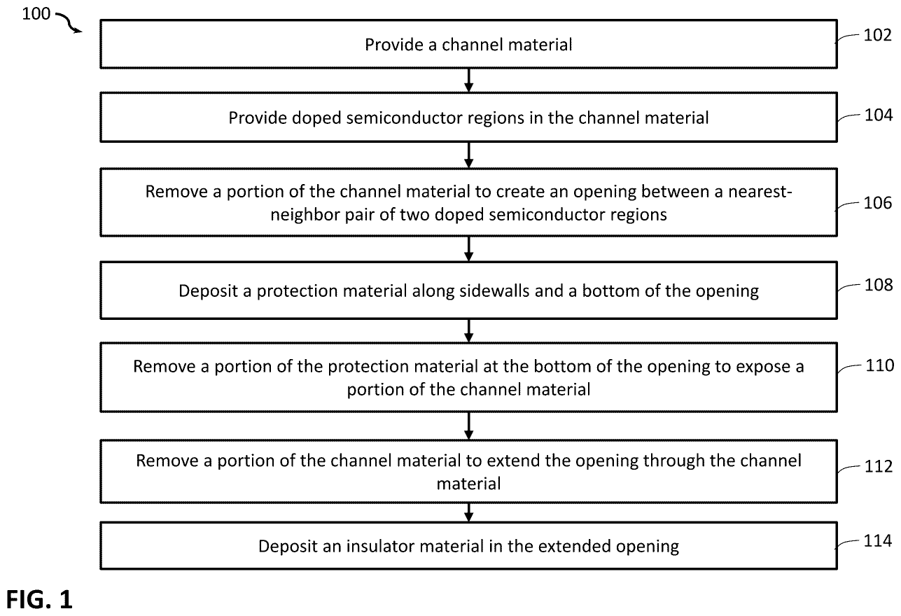

FIG. 1 provides a flow diagram of an example method 100 of fabricating an integrated circuit (IC) device with a protection liner between doped semiconductor regions, in accordance with various embodiments of the present disclosure.

Although the operations of the method 100 are illustrated once each and in a particular order, the operations may be performed in any suitable order and repeated as desired. For example, one or more operations may be performed in parallel to manufacture, substantially simultaneously, an IC device with a protection liner between doped semiconductor regions to protect the doped semiconductor regions from damage during an etching process as described herein. In another example, the operations may be performed in a different order to reflect the structure of a particular device assembly in which one or more protection liners are deposited to protect the doped semiconductor regions from damage during an etching process as described herein will be included.

In addition, the example manufacturing method 100 may include other operations not specifically shown in FIG. 1, such as various cleaning or planarization operations as known in the art. For example, in some embodiments, a support structure, as well as layers of various other materials subsequently deposited thereon, may be cleaned prior to, after, or during any of the processes of the method 100 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the method 100 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

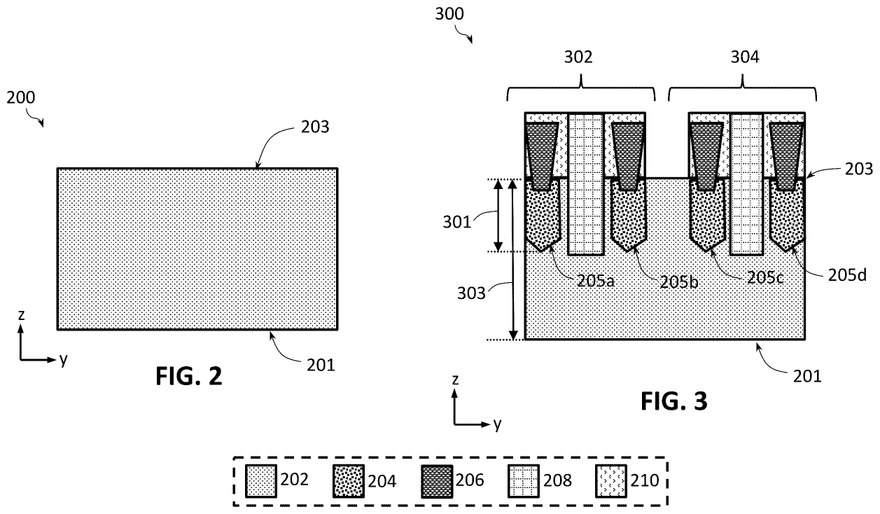

Various operations of the method 100 may be illustrated with reference to the example embodiments shown in FIGS. 2-8, illustrating cross-sectional side views for various stages in the manufacture of an example IC device that includes a protection liner between doped semiconductor regions to protect the doped semiconductor regions from damage during an etching process, in accordance with some embodiments. In particular, the illustration of each of FIGS. 2-8 shows a cross-section side view of an IC structure in an y-z plane, where the doped semiconductor regions are spaced apart from each other in a direction along the y-axis.

A number of elements referred to in the description of FIGS. 2-8 with reference numerals are illustrated in these figures with different patterns, with a legend showing the correspondence between the reference numerals and patterns being provided at the bottom of each drawing page containing FIGS. 2-8. For example, the legend illustrates that FIGS. 2-8 use different patterns to show a channel material 202, a doped semiconductor material 204, a contact material 206, a gate structure 208, an insulator material 210, etc. Furthermore, although a certain number of a given element may be illustrated in some of FIGS. 2-8 (e.g., four doped semiconductor regions 205), this is simply for ease of illustration, and more, or less, than that number may be included in an IC structure fabricated according to the method 100. Still further, various views shown in FIGS. 2-8 are intended to show relative arrangements of various elements therein. In other embodiments, various IC devices with a protection liner between doped semiconductor regions to protect the doped semiconductor regions from damage during an etching process, or portions thereof, may include other elements or components that are not illustrated (e.g., gate dielectric and a gate electrode in the gate structure, etc.).

Turning to FIG. 1, the method 100 may begin with a process 102 that includes providing a channel material. An IC structure 300, depicted in FIG. 2, illustrates an example result of the process 102. As shown in FIG. 2, the IC structure 200 includes a channel material 202 having a first face 201 and a second face 203, where the second face 203 may be opposite the first face 201. In some examples, the channel material 202 may be over a support structure (e.g., a die, a wafer, a substrate, a package substrate, or a carrier substrate), and the first face 201 and the second face 203 may be substantially parallel to the support structure.

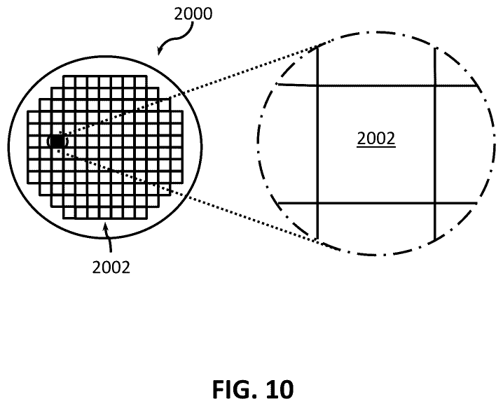

Implementations of the present disclosure may be formed or carried out on any suitable support structure, such as a substrate, a die, a wafer, or a chip. The support structure may, e.g., be the wafer 2000 of FIG. 10, discussed below, and may be, or be included in, a die, e.g., the singulated die 2002 of FIG. 10, discussed below. The support structure may be a semiconductor substrate composed of semiconductor material systems including, for example, N-type or P-type materials systems, and, in some embodiments, the channel material 202, described herein, may be a part of such a support structure. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. Although a few examples of materials from which the support structure may be formed are described here, any material that may serve as a foundation upon which an IC may be built falls within the spirit and scope of the present disclosure. In various embodiments, the support structure may include any such substrate, possibly with some layers and/or devices already formed thereon, not specifically shown in the present figures, providing a suitable surface for forming doped semiconductor regions with a protection liner therebetween to protect the doped semiconductor regions from damage during an etching process. As used herein, the term “support structure” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure may provide material “support” in that, e.g., the IC devices/structures described herein are build based on the semiconductor materials of the support structure. However, in some embodiments, the support structure of the IC devices described herein may provide mechanical support

Further, in general, the channel material 202 may be composed of semiconductor material systems including, for example, N-type or P-type materials systems. In some embodiments, the channel material 202 may include a high mobility oxide semiconductor material, such as tin oxide, antimony oxide, indium oxide, indium tin oxide, titanium oxide, zinc oxide, indium zinc oxide, indium gallium zinc oxide, gallium oxide, titanium oxynitride, ruthenium oxide, or tungsten oxide. In general, the channel material 202 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material 202 may have a thickness between about 5 and 30 nanometers, including all values and ranges therein. Further, in general, the channel material 202 may have any suitable shapes, for example, a fin, a nanowire, a nanoribbon, a plane, etc.

The method 100 may further include a process 104, which may include providing doped semiconductor regions in the channel material. An IC structure 300, depicted in FIG. 3, illustrates an example result of the process 104. As shown in FIG. 3, the IC structure 300 may further include doped semiconductor regions 205 (individually shown as 205a, 205b, 205c, and 205d) in the channel material 202. The doped semiconductor regions 205 may be spaced apart from each other along the y-axis. Each doped semiconductor region 205 may include doped semiconductor materials 204. Each of the first and second doped semiconductor regions may extend from the second face 203 of the channel material 202 towards the first face 201 of the channel material. As shown, the doped semiconductor regions 205 may extend from the second face 203 towards the first face 201 by a first distance 301 (e.g., a dimension along the z-axis). The first distance 301 is less than the thickness 303 of the channel material 202. That is, the doped semiconductor regions 205 may extend into a portion of the channel material 202 but without reaching first face 201. While FIG. 3 illustrates that each of the doped semiconductor region 205 extends from the second face 203 towards the first face 201 by the same first distance 301, different doped semiconductor regions 205 can extend into the channel material 202 by different distances (e.g., without reaching the first face 201.

In the illustrated example of FIG. 3, the doped semiconductor regions 205 may correspond to S/D regions of transistors. For instance, the doped semiconductor regions 205a and 205b may be S/D regions of a transistor 302, and the doped semiconductor regions 205c and 205d may be S/D regions of another transistor 304. In one example, the doped semiconductor region 205a may be a source region of the transistor 302, the doped semiconductor region 205b may be a drain region of the transistor 302, the doped semiconductor region 205c may be a source region of the transistor 304, and the doped semiconductor region 205d may be a drain region of the transistor 304. In another example, the doped semiconductor region 205a may be a drain region of the transistor 302, the doped semiconductor region 205b may be a source region of the transistor 302, the doped semiconductor region 205c may be a drain region of the transistor 304, and the doped semiconductor region 205d may be a source region of the transistor 30.

In general, the doped semiconductor regions 205 may be formed at the process 104 using either an implantation/diffusion process or an etching/deposition process. In the former process, dopants such as boron, aluminum, antimony, phosphorous, or arsenic may be ion-implanted into the channel material 202 to form the doped semiconductor regions 205. An annealing process that activates the dopants and causes them to diffuse further into the channel material 202 may follow the ion implantation process. In the latter process, a portion of the channel material 202 may first be etched to form a recess at the location of the future doped semiconductor region 205. An epitaxial deposition process may then be carried out to fill the recess with material that is used to fabricate the doped semiconductor regions 205. In some implementations, the doped semiconductor regions 205 may be fabricated using a silicon alloy such as silicon germanium or silicon carbide. In some implementations the epitaxially deposited silicon alloy may be doped in situ with dopants such as boron, arsenic, or phosphorous. In further embodiments, the doped semiconductor regions 205 may be formed using one or more alternate semiconductor materials such as germanium or a group III-V material or alloy. And in further embodiments, one or more layers of metal and/or metal alloys may be used to form the doped semiconductor regions 205.

As further shown in FIG. 3, the IC structure 300 may include contacts 206, where each doped semiconductor region 205 may have a contact 206 extending into a portion of the doped semiconductor regions 205. In general, the contacts 206 may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

As further shown in FIG. 3, the IC structure 300 may include an insulator material 210 to provide electrical isolation, for example, between the source contacts 206, drain contacts 206, and the gate structure 208 in each of the transistors 302 and 304. In general, the insulator material 210 may be any suitable interlayer dielectric (ILD) material. In some embodiments, the insulator material 210 may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material 210 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

In general, the insulator material 210 may be provided at the process 104 using a technique such as spin-coating, dip-coating, atomic layer deposition (ALD), chemical vapor deposition (CVD), or physical vapor deposition (PVD), (e.g., evaporative deposition, magnetron sputtering, or e-beam deposition). In some embodiments, the insulator material 210 may be provided over the doped semiconductor regions 205, an opening may be created in the insulator material 210, and the contacts 206 may be formed in the opening of the insulator material 210, for example, by depositing one or more electrically conductive materials along sidewalls of the opening, followed by silicide annealing and a contact metal fill with an electrically conductive material. The electrically conductive material may be as discussed above.

As further shown in FIG. 3, the IC structure 300 may include a gate structure 208 between the source and drain regions of each of the transistors 302 and 304. For example, a gate structure 208 may be between the doped semiconductor regions 205a and 205b, and another gate structure 208 may be between the doped semiconductor regions 205c and 205d. In some examples, the gate structure 208 may be a dummy gate structure. In general, a gate electrode material and a gate dielectric may be deposited at the location of the gate structure 208 using any suitable techniques (e.g., CVD, PVD, ALD, etc.) to form a transistor gate. The transistor gate may be formed during any suitable stages of the fabrication, for example, before the process 104, as part of the process 104, or after performed the method 100.

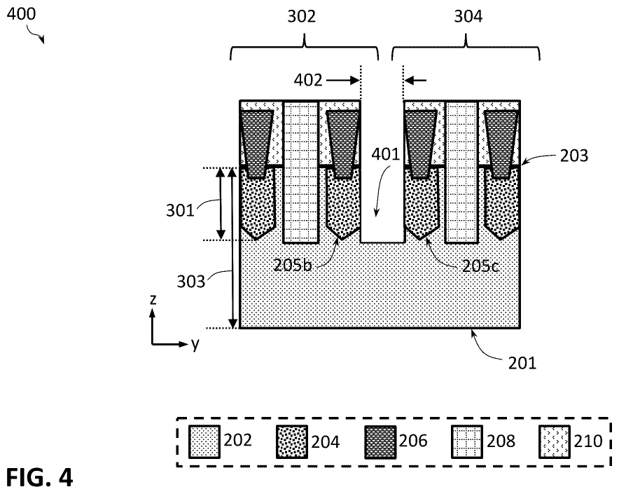

The method 100 may further include a process 106, which may include removing a portion of the channel material to create an opening between a nearest-neighbor pair of two of the doped semiconductor regions. An IC structure 400, depicted in FIG. 4, illustrates an example result of the process 106. As shown in FIG. 4, the IC structure 400 includes an opening 401 between the doped semiconductor region 205b and the doped semiconductor region 205c. More specifically, the opening 401 may be created between a nearest-neighbor pair of two of the doped semiconductor regions 205 (e.g., the doped semiconductor regions 205b and 205c) with no gate structure 208 therebetween. Stated differently, the opening 401 may be created between a source region of one transistor and a drain region of another transistor. In some examples, the opening 401 may have a width 402 (in a dimension along the y-axis) between about 18 and 27 nanometers (e.g., between about 20 and 25 nanometers). In some examples, the width 402 of the opening 401 may be substantially the same as a distance between the nearest-neighbor pair of two of the doped semiconductor regions 205b and 205c. That is, the removal of the portion of the channel material 202 may expose portions of the sidewalls of the doped semiconductor regions 205b and 205c.

In some embodiments, the opening 401 may be created in the process 106 using any suitable etching technique (e.g., a dry etch, such as e.g., radio frequency (RF) reactive ion etch (RIE) or inductively coupled plasma (ICP) RIE) in combination with lithography (e.g., photolithography or electron-beam lithography) to define the locations and the sizes of these openings. In some embodiments, the etches performed in the process 106 to form the opening 401 may include an anisotropic etch, using etchants in a form of e.g., chemically active ionized gas (i.e., plasma) using e.g., bromine (Br) and chloride (CI) based chemistries. An etch is described as “anisotropic” if etchants remove the material preferentially in one direction and not in all directions. In some embodiments, during the etches of the process 106, the IC structure 400 may be heated to elevated temperatures, e.g., to temperatures between about room temperature and 200 degrees Celsius, including all values and ranges therein, to promote that byproducts of the etch are made sufficiently volatile to be removed from the surface.

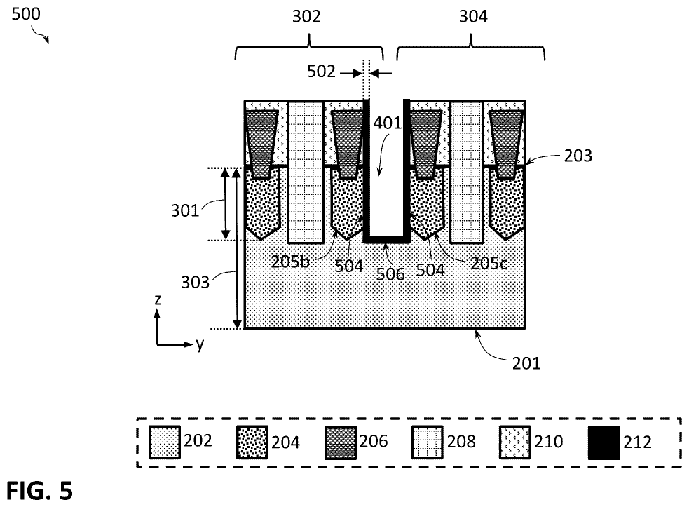

The method 100 may further include a process 108, which may include depositing a protection material (or a liner material) along sidewalls and a bottom of the opening created in the process 106. For example, the protection material may be conformally deposited over and in the opening. An IC structure 500, depicted in FIG. 5, illustrates an example result of the process 108. As shown in FIG. 5, the IC structure 500 includes a liner material 212 on the sidewalls 504 and the bottom 506 of the opening 401. As a result of the deposition of the liner material 212, the opening 401 may become narrower.

While FIG. 5 illustrates the doped semiconductor regions 205b and 205 to be aligned with the liner material 212 (extend into the channel material 202 by the same distance 301), aspects are not limited thereto. For example, in some instances, the doped semiconductor regions 205b and 205c extend to a smaller distance than the liner material 212, to ensure that all the surfaces of the doped semiconductor regions 205b and 205c are protected by the liner material 212 (from a subsequent process such as etching). In other instances, the doped semiconductor regions 205b and 205c may extend a bit further (into the channel material 202) than the liner material 212, in which case the liner material 212 may still provide protection to a large portion of the doped semiconductor regions 205b and 205c surfaces even though some may be unprotected. In any case, the inclusion of the liner material 212 can protect at least some portions of the doped semiconductor regions 205b and 205c surfaces, and thus can provide improvement.

In some embodiments, the liner material 212 may be in a layer (e.g., a thin film) having a thickness 502 between about 0.5 and 2.5 nanometers (e.g., between about 1 and 2 nanometers or about 1.5 nanometers). In some examples, the thickness of the layer of liner material 212 may be substantially uniform along the sidewall 504 and the bottom 506 of the opening 401.

In some embodiments, the liner material 212 may include an oxide material (e.g., aluminum oxide (Al2O3) or hafnium oxide (HfO2)). In some embodiments, the liner material 212 may be etch-selective with respect to the channel material 202. Stated differently, when etchants used to etch the channel material 202 at a subsequent process 108 may not substantially etch the liner material 212, enabling selective etching of the channel material 202 but not the liner material 212. In general, the liner material 212 may be a strong and tough material that can be used to form a thin film to protect the doped semiconductor regions 205b and 205c from damage caused by etching, for example, at the subsequent process 108.

In general, the liner material 212 be deposited at the process 108 using CVD, PVD, ALD, any other suitable processes, and/or combinations thereof. In certain examples, the liner material 212 may be deposited at the process 108 using ALD.

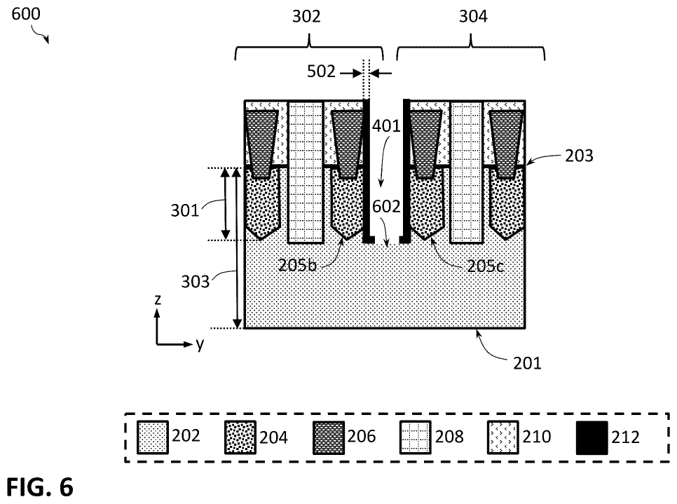

The method 100 may further include a process 110, which may include removing at least a portion of the protection material at the bottom of the opening to expose a portion of the channel material. An IC structure 600, depicted in FIG. 6, illustrates an example result of the process 110. As shown in FIG. 6, a portion of the liner material 212 at the bottom of opening 401 is removed, and thus a portion 602 of the channel material 202 in the IC structure 600 is exposed. In general, the portion of the liner material 212 may be removed at the process 110 by any suitable etching techniques as discussed above. In certain examples, an anisotropic etching may be performed.

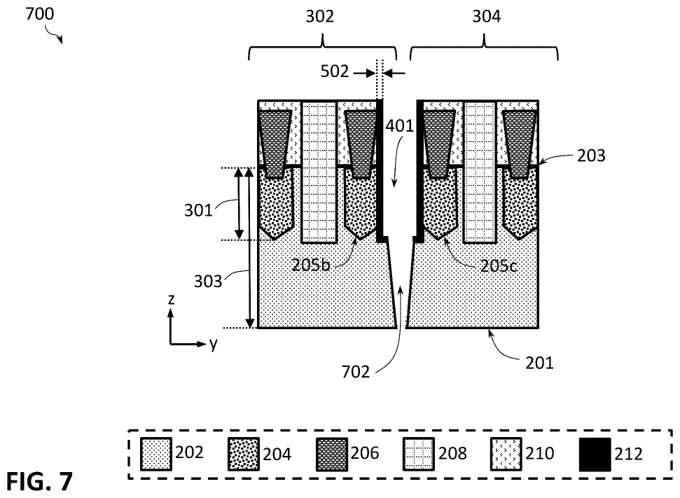

The method 100 may further include a process 112, which may include removing a portion of the channel material to extend the opening through the channel material. In some instances, the method 100 may or may not include the process 110. In any case, the process 112 may extend the opening (created at the process 106) beyond the protection material (deposited at the process 108) to form the extended opening. An IC structure 700, depicted in FIG. 7, illustrates an example result of the process 112. As shown in FIG. 7, the opening 401 is extended through the channel material 202, for example, creating an opening (or cut region) 702 through the entire thickness 303 of the channel material 202. In some examples, the opening 702 may have varying widths through the channel material 202 along the z-axis. In general, the portion of the channel material 202 may be removed at the process 112 using an anisotropic etching technique. In some examples, the portion of the channel material 202 may be removed at the process 112 using an ionic (e.g., argon ions) bombardment-based etch. In general, a chemical-based etching may not be suitable for the process 112.

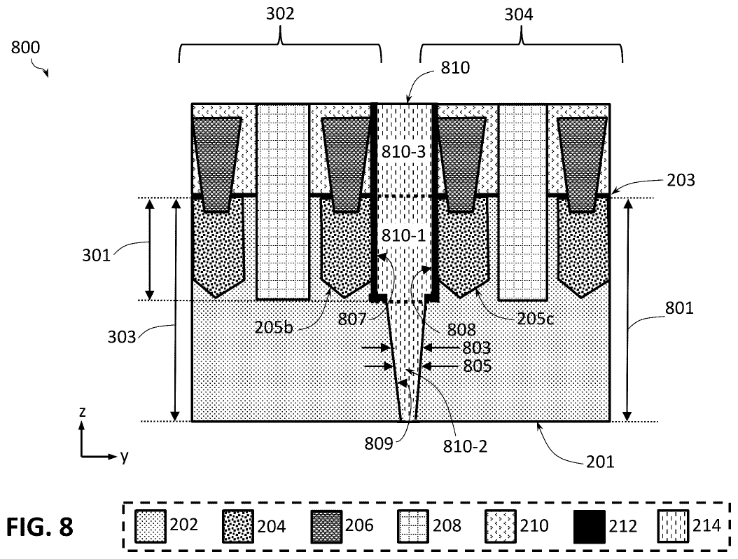

The method 100 may further include a process 114, which may include depositing an insulator material in the extended opening. For instance, the insulator material may fill the lined opening and at least some portions of the cut region (e.g., the cut region 702) in the channel material. In other words, the extended opening may at least partially be filled with the insulator material. An IC structure 800, depicted in FIG. 8, illustrates an example result of the process 114. A shown in FIG. 8, the IC structure 800 includes an insulator structure 810 in a portion of the channel material 202 between the doped semiconductor regions 205b and 205c (between the adjacent transistors 302 and 304). The insulator structure 810 may extend from the second face 203 of the channel material 202 towards the first face 201 of the channel material 202 by a second distance 801. The second distance 801 may be greater than the first distance 303 (into which the doped semiconductor regions 205 extend from the second face 203 of the channel material 202). In some instances, the insulator structure 810 can extend through the entire thickness of the channel material 202 as shown in FIG. 8, and thus the second distance 801 may correspond a distance (or the thickness 303) between the first face 201 and the second face 203 of the channel material 202.

Further, the insulator structure 810 may have a first portion 810-1, a second portion 810-2, and a third portion 810-3. The first portion 810-1 may be a portion of the insulator structure 810 that extends from the second face 203 of the channel material 202 to about the first distance 301. The second portion 810-2 may be a portion of the insulator structure 810 that extends from about the first distance 301 to the second distance 801. The third portion 810-3 may be a portion of the insulator structure 810 that extends away from the channel material 202.

As further shown in FIG. 8, the liner material 212 deposited at the process 108 may be on at least portions of sidewalls 807 and 808 of the insulator structure 810 in the first portion 810-1 but may be absent on at least portions of the sidewalls (e.g., shown by 809) of the insulator structure 810 in the second portion 810-2 (of the insulator structure 810). In certain embodiments, the liner material 212 may be absent on all portions of the sidewalls of the insulator structure 810 in the second portion 810-2 as shown in FIG. 8.

As further shown in FIG. 8, the insulator structure 800 may include an insulator material 214. The insulator material 214 may be on at least a portion of a sidewall 807 of the insulator structure 810 that is closest to the doped semiconductor region 205b, where the liner material 212 is between the insulator material 214 and the doped semiconductor region 205b. Similarly, the insulator material 214 may also be on a portion of a sidewall 808 of the insulator structure 810 that is closest to the doped semiconductor region 205c, where the liner material 214 is between the insulator material 214 and the doped semiconductor region 205c. Further, on the portion of the sidewall 807 of the insulator structure 810 that is closest to the doped semiconductor region 205b, the liner material 212 may be in contact with the doped semiconductor region 205b. Similarly, on the portion of the sidewall 808 of the insulator structure 810 that is closest to the doped semiconductor region 205c, the liner material 212 may be in contact with the doped semiconductor region 205c.

In some embodiments, the insulator material 214 in at least a portion of the second portion 810-2 of the insulator structure 810 may be in contact with the channel material 202. As discussed above with reference to the process 110, the opening 702 in the channel material 202 may have varying widths. Accordingly, in some embodiments, a width (e.g., shown by 803) of a sub-portion (e.g., a first sub-portion) of the second portion 810-2 of the insulator structure 810 may be smaller than a width (e.g., shown by 805) of another sub-portion (e.g., a second sub-portion) of the second portion 810-2 of the insulator structure 810. The width 803 of the first sub-portion and the width 805 of the second sub-portion may be in a dimension measured in a direction substantially parallel to a support over which the IC device is provided. As further shown, an average width of the first portion 810-1 of the insulator structure is greater than an average width of the second portion 810-2 of the insulator structure 810.

In general, the insulator material 214 may be any suitable dielectric material as discussed above with reference to the insulator material 210. In some embodiments, the insulator material 214 may have the same composition of material(s) as the insulator material 210. In other embodiments, the insulator material 214 may have different composition of material(s) than the insulator material 210. Further, the insulator material deposited at the process 112 may be performed using any suitable techniques, such as, but not limited to, ALD, CVD, PVD, PECVD.

While FIG. 8 illustrates the extended opening (the opening lined opening and the cut region 702) filled completely with the insulator material 214, aspects are not limited thereto. For example, in some instances, there may be one or more gaps in the extended opening without the insulator material 214. In certain examples, the insulator material 214 may not be filled all the way to the first face 201. For instance, there may be a gap in the extended opening near the first face 201. For instance, the insulator material 214 may stop at a third distance from the second face 203, before reaching the first face 201.

As discussed above, in some instances, the channel material 202 may be in the shape of a fin, and thus the process 112 in which a portion of the channel material 202 is removed to extend the opening 401 through the channel material 202 may be referred to as a fin trim isolation (FTI) process.

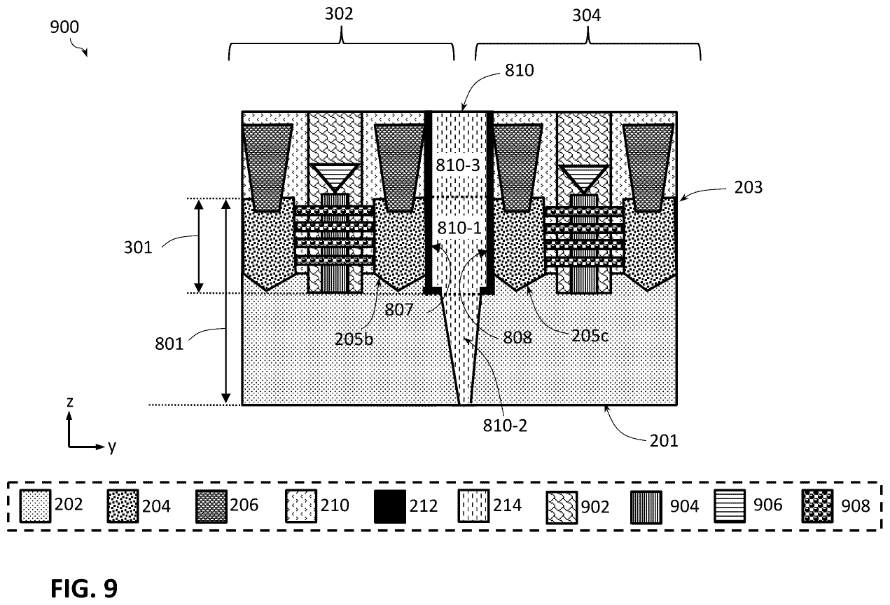

FIG. 9 illustrates a cross-sectional side view of an example IC device 900 with a protection liner between doped semiconductor regions, in accordance with some embodiments of the present disclosure. The IC device 900 may be fabricated using the method 100 discussed above with reference to FIGS. 1-8. Similar to FIGS. 2-8, a legend provided within a dashed box at the bottom of FIG. 9 illustrates colors/patterns used to indicate some of the elements of the IC device 100 so that FIG. 9 is not cluttered by too many reference numerals. Further, for simplicity, FIG. 9 may use the reference numerals as in FIGS. 2-8 to refer to the same materials and/or structures as in FIG. 2-8. Generally speaking, the IC device 900 may be similar to the IC structure 800 in many respects. For instance, the IC device 900 may include a channel material 202, doped semiconductor regions 205 extending into a portion of the channel material 202 and spaced apart from each other, and an insulator structure 810 in a portion of the channel material between a nearest-neighbor pair of doped semiconductor regions 205 (shown as 205b and 205c), where the insulator structure 810 may include a liner material 212 on at least portions of the sidewalls 807 and 808 of the insulator structure 810. The channel material 202, the doped semiconductor regions 205, and the insulator structure 810 in FIG. 9 may take the form of any of the embodiments of those components discussed above with reference to FIGS. 1-8, which descriptions, therefore, are not repeated here in the interests of brevity.

As shown in FIG. 9, the IC device 900 may further include stacks of nanoribbons 908 over the channel material 202. The nanoribbons 908 may extend substantially parallel to a support structure (e.g., a die, a wafer, a substrate, a package substrate, or a carrier substrate) over which the channel material 202 is provided. The nanoribbon 908 may take the form of a nanowire or nanoribbon, for example. In some embodiments, an area of a transversal cross-section of the nanoribbon 908 (i.e., an area in the x-z plane) may be between about 25 and 10000 square nanometers, including all values and ranges therein (e.g., between about 25 and 1000 square nanometers, or between about 25 and 500 square nanometers). In some embodiments, a width of the nanoribbon 908 (i.e., a dimension measured in a plane parallel to a support structure on which the channel material 202 is provided, e.g., along the y-axis of the example coordinate system shown in FIG. 9) may be at least about 3 times larger than a height of the nanoribbon 908 (i.e., a dimension measured in a plane perpendicular to a support structure on which the channel material 202 is provided, e.g., along the z-axis of the example coordinate system shown in FIG. 9), including all values and ranges therein, e.g., at least about 4 times larger, or at least about 5 times larger. Although the nanoribbon 908 illustrated in FIG. 9 is shown as having a rectangular cross-section, the nanoribbon 908 may instead have a cross-section that is rounded at corners or otherwise irregularly shaped, and the gate stack (the gate dielectric 904 and the gate electrode 906) may conform to the shape of the nanoribbon 908. The term “face” of a nanoribbon may refer to the side of the nanoribbon 908 that is larger than the side perpendicular to it (along the direction of the y-axis of the example coordinate system shown in FIG. 9), the latter side being referred to as a “sidewall” of a nanoribbon.

In various embodiments, the semiconductor material of the nanoribbon 908 may be composed of semiconductor material systems including, for example, N-type or P-type materials systems. In some embodiments, the nanoribbon 908 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 908 may include a combination of semiconductor materials. In some embodiments, the nanoribbon 908 may include a monocrystalline semiconductor, such as silicon (Si) or germanium (Ge). In some embodiments, the nanoribbon 908 may include a compound semiconductor with a first sub-lattice of at least one element from group III of the periodic table (e.g., Al, Ga, In), and a second sub-lattice of at least one element of group V of the periodic table (e.g., P, As, Sb).

The IC device 900 may further include a gate dielectric 904 and a gate electrode 906 between the doped semiconductor regions 205a and 205b and between the doped semiconductor regions 205c and 205d. For instance, the gate dielectric 904 and a gate electrode 906 may be part of the gate structure 208 discussed above with reference to FIGS. 2-8. In some embodiments, the gate dielectric material 904 may wrap around at least portions of the nanoribbons 908.

The gate dielectric 904 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 904 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 904 during manufacture of the IC device 900 to improve the quality of the gate dielectric 904. In some embodiments, the gate dielectric 904 may have a thickness between about 0.5 nanometers and 3 nanometers, including all values and ranges therein, e.g., between about 1 and 3 nanometers, or between about 1 and 2 nanometers.

In some embodiments, the gate dielectric 904 may be a multilayer gate dielectric, e.g., it may include any of the high-k dielectric materials in one layer and a layer of IGZO. In some embodiments, the gate stack (i.e., a combination of the gate dielectric 904 and the gate electrode 906) may be arranged so that the IGZO is disposed between the high-k dielectric and the channel material 202. In such embodiments, the IGZO may be in contact with the channel material 202 and may provide the interface between the channel material 202 and the remainder of the multilayer gate dielectric 904. The IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10).

The gate electrode 906 may include at least one P-type work function metal or N-type work function metal, depending on whether the S/D electrodes 326 are to be included in a PMOS transistor or an NMOS transistor. For a PMOS transistor, metals that may be used for the gate electrode 906 may include, but are not limited to, ruthenium, palladium, platinum, cobalt, nickel, and conductive metal oxides (e.g., ruthenium oxide). For an NMOS transistor, metals that may be used for the gate electrode 906 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 906 may consist of a stack of two or more metal layers, where one or more metal layers are work function metal layers and at least one metal layer is a fill metal layer. Further metal layers may be included for other purposes, such as to act as a barrier layer.

The IC device 900 may further include an insulator material 902 that surrounds the gate stack (the gate dielectric 904 and the gate electrode 906). In general, the insulator material 902 may be any suitable dielectric material as discussed above with reference to the insulator material 210. In some embodiments, the insulator material 902 may have the same composition of material(s) as the insulator material 210 and/or the insulator material 214. In other embodiments, the insulator material 902 may have different composition of material(s) than the insulator material 210 and/or 214.

In some embodiments, an IC device implemented using the method 100 discussed above with reference to FIGS. 2-9 may include a semiconductor material (e.g., a first semiconductor material) having a first face and a second face opposite the first face. The IC device my further include an insulator structure including a protectional material (e.g., the liner material 212) and an insulator material (e.g., the insulator material 214). The insulator structure may extend from the second face of the semiconductor material towards the first face of the semiconductor material. In some instances, the semiconductor material and the insulator structure may correspond respectively to the channel material 202 and the insulator structure 810 discussed above with reference to FIGS. 2-9. The insulator structure may include a first portion and a second portion. The first portion (e.g., the portion 810-1) may extend from the second face of the semiconductor material to a first distance from the second face of the semiconductor material. The second portion (e.g., the portion 810-2) may extend from the first distance (from the second face of the semiconductor material) to a second distance (from the second face of the semiconductor material). In the first portion, the protection material may be between the insulator material and the semiconductor material, and in at least a portion of the second portion, the insulator material may be in contact with the semiconductor material.

In some embodiments of the IC device, the protection material may be in a layer having a thickness 502 between about 0.5 and 2.5 nanometers (e.g., between about 1 and 2 nanometers or about 1.5 nanometers). In some embodiment, the protection material may include at least one of aluminum and oxygen (e.g., aluminum oxide) or hafnium and oxygen (e.g., hafnium oxide). In some embodiments, the IC device may further include a first doped semiconductor region and a second doped semiconductor region at least partially in the semiconductor material. The first and second doped semiconductor regions may extend from the second face of the semiconductor material towards the first face of the semiconductor material by the first distance. In some instances, the first doped semiconductor region may correspond respectively to the doped semiconductor region 205b and the second doped semiconductor region may correspond to the doped semiconductor region 205c. In some embodiments, the insulator material may be on a portion of a sidewall of the insulator structure closest to the first doped region, and the protection material may be between the insulator material and the first doped region. Further, the insulator material may be on a portion of a sidewall of the insulator structure that is closest to the second doped region, and the protection material is between the insulator material and the second doped region. In some embodiments of the IC device, the IC device may further include a stack of nanoribbons (e.g., the nanoribbons 908) extending, along an axis about parallel to the first face, between the first doped semiconductor region and the second doped semiconductor region. The stack of nanoribbons may include a second semiconductor material (e.g., the same as or different than the first semiconductor material).

IC devices with a protection liner between doped semiconductor regions as disclosed herein may be included in any suitable electronic device. FIGS. 10-14 illustrate various examples of devices and components that may include at least one IC device with one or more nearest-neighboring pairs of doped semiconductor regions with a protection liner therebetween as disclosed herein.

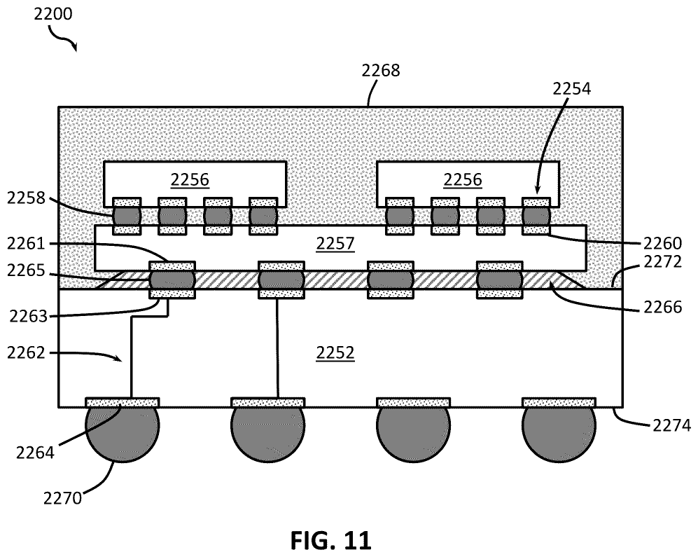

FIG. 10 illustrates top views of a wafer 2000 and dies 2002 that may include one or more IC devices with a protection liner between doped semiconductor regions in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 11. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., IC devices including at least one nearest-neighboring pairs of doped semiconductor regions with a protection liner therebetween as described herein). After the fabrication of the semiconductor product is complete (e.g., after manufacture of at least one nearest-neighboring pairs of doped semiconductor regions with a protection liner therebetween as described herein, e.g., after manufacture of any embodiment of the IC devices shown in FIGS. 1-3, or any further embodiments of these devices, described herein), the wafer 2000 may undergo a singulation process in which each of the dies 2002 is separated from one another to provide discrete “chips” of the semiconductor product. In particular, IC devices with a protection liner between doped semiconductor regions as disclosed herein may take the form of the wafer 2000 (e.g., not singulated) or the form of the die 2002 (e.g., singulated). The die 2002 may include at least one nearest-neighboring pairs of doped semiconductor regions having protection liner (e.g., one or more nearest-neighboring pairs of doped semiconductor regions 205 with a protection liner 212 therebetween as described herein), as well as, optionally, supporting circuitry to route electrical signals to the at least one nearest-neighboring pair of doped semiconductor regions with a protection liner therebetween, as well as any other IC components. In some embodiments, the wafer 2000 or the die 2002 may implement an RF FE device, a memory device (e.g., a static random access memory (SRAM) device), a logic device (e.g., an AND, OR, NAND, or NOR gate), or any other suitable circuit element. Multiple ones of these devices may be combined on a single die 2002.

FIG. 11 is a side, cross-sectional view of an example IC package 2200 that may include one or more IC devices with a protection liner between doped semiconductor regions in accordance with any of the embodiments disclosed herein. In some embodiments, the IC package 2200 may be a system-in-package (SiP).

As shown in FIG. 11, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 11 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 11 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

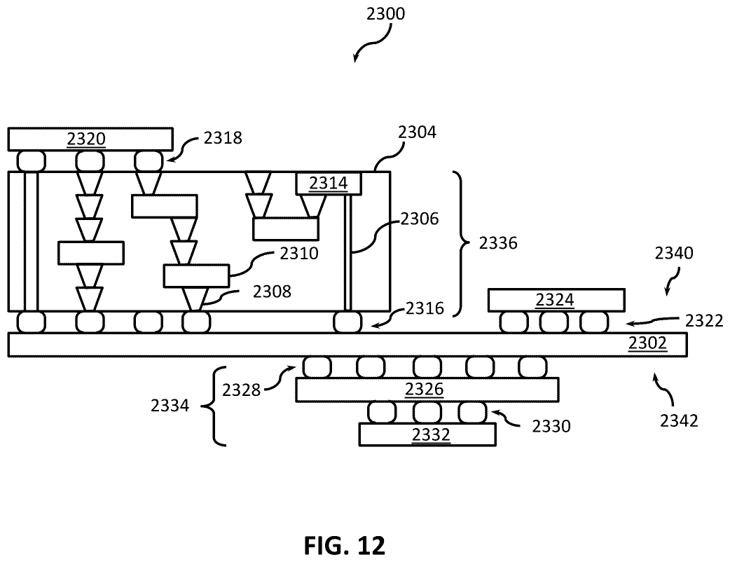

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 11 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein and may include any of the embodiments of an IC device having at least one nearest-neighboring pairs of doped semiconductor regions with a protection liner therebetween, e.g., any of the IC devices shown in FIGS. 1-3, or any further embodiments of at least one nearest-neighboring pairs of doped semiconductor regions with a protection liner therebetween, described herein. In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be RF FE dies and/or logic dies, including at least one nearest-neighboring pairs of doped semiconductor regions with a protection liner therebetween as described herein, one or more of the dies 2256 may be memory dies (e.g., high bandwidth memory), etc. In some embodiments, any of the dies 2256 may include at least one nearest-neighboring pairs of doped semiconductor regions with a protection liner therebetween, e.g., as discussed above; in some embodiments, at least some of the dies 2256 may not include any nearest-neighboring pairs of doped semiconductor regions with a protection liner therebetween.

The IC package 2200 illustrated in FIG. 11 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 11, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 12 is a cross-sectional side view of an IC device assembly 2300 that may include components having one or more IC devices implementing at least one nearest-neighboring pairs of doped semiconductor regions with a protection liner therebetween in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing at least one nearest-neighboring pairs of doped semiconductor regions with a protection liner therebetween in accordance with any of the embodiments disclosed herein; e.g., any of the IC packages discussed below with reference to the IC device assembly 2300 may take the form of any of the embodiments of the IC package 2200 discussed above with reference to FIG. 11 (e.g., may include at least nearest-neighboring pairs of doped semiconductor regions with a protection liner therebetween in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 12), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 10B), an IC device (e.g., the IC device of FIGS. 1-3), or any other suitable component. In particular, the IC package 2320 may include at least one nearest-neighboring pairs of doped semiconductor regions with a protection liner therebetween as described herein. Although a single IC package 2320 is shown in FIG. 12, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 12, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing at least one nearest-neighboring pairs of doped semiconductor regions with a protection liner therebetween as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

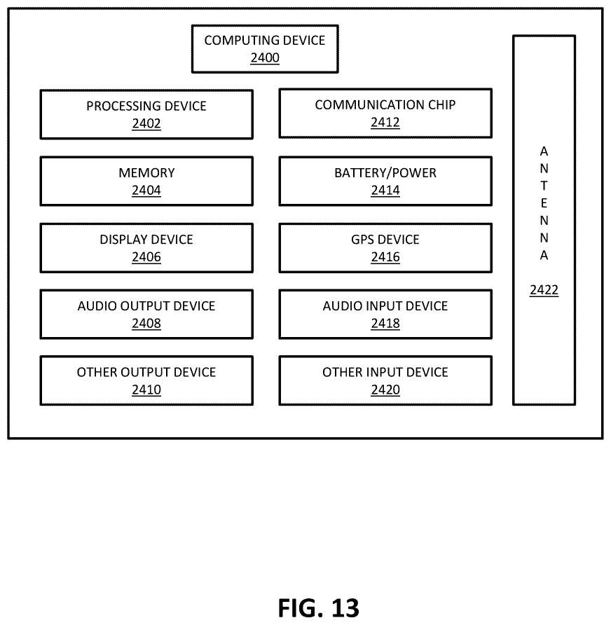

FIG. 13 is a block diagram of an example computing device 2400 that may include one or more components with one or more IC devices having at least one nearest-neighboring pair of doped semiconductor regions with a protection liner therebetween in accordance with any of the embodiments disclosed herein. For example, any suitable ones of the components of the computing device 2400 may include a die (e.g., the die 2002 (FIG. 10B)) including at least one nearest-neighboring pair of doped semiconductor regions with a protection liner therebetween in accordance with any of the embodiments disclosed herein. Any of the components of the computing device 2400 may include an IC device (e.g., any embodiment of the IC device of FIGS. 1-3) and/or an IC package 2200 (FIG. 11). Any of the components of the computing device 2400 may include an IC device assembly 2300 (FIG. 12).

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with at least one nearest-neighboring pair of doped semiconductor regions with a protection liner therebetween as described herein may be particularly advantageous for use within the one or more communication chips 2412, described above. For example, such IC devices with at least one nearest-neighboring pair of doped semiconductor regions with a protection liner therebetween may be used to implement one or more of power amplifiers, low-noise amplifiers, filters (including arrays of filters and filter banks), switches, upconverters, downconverters, and duplexers, e.g., as a part of implementing an RF transmitter, an RF receiver, or an RF transceiver.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

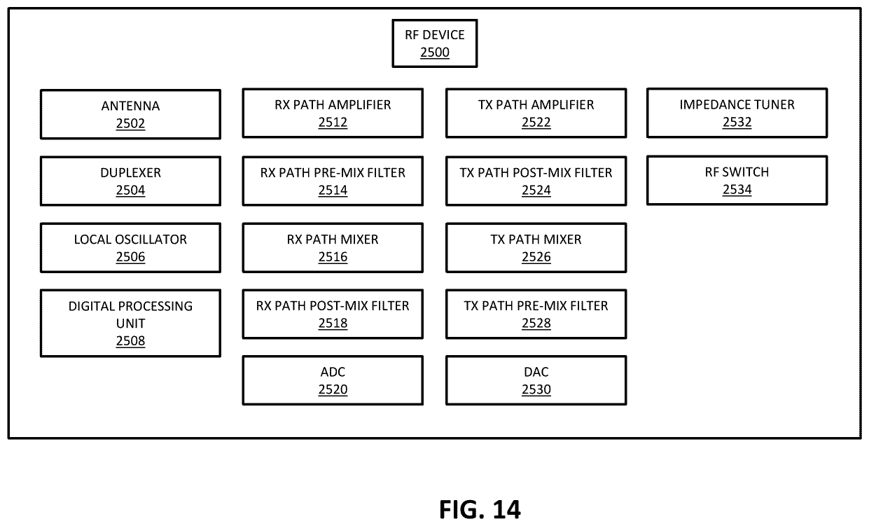

FIG. 14 is a block diagram of an example RF device 2500 that may include one or more components with one or more IC devices having at least one nearest-neighboring pair of doped semiconductor regions with a protection liner therebetween in accordance with any of the embodiments disclosed herein. For example, any suitable ones of the components of the RF device 2500 may include a die (e.g., the die 2002 as described with reference to FIG. 12 or a die implementing the IC device as described with reference to FIGS. 1-3) including at least one nearest-neighboring pair of doped semiconductor regions with a protection liner therebetween in accordance with any of the embodiments disclosed herein. Any of the components of the RF device 2500 may include an IC device (e.g., the IC device of FIGS. 1-3) and/or an IC package 2200 as described with reference to FIG. 11. Any of the components of the RF device 2500 may include an IC device assembly 2300 as described with reference to FIG. 12. In some embodiments, the RF device 2500 may be included within any components of the computing device 2400 as described with reference to FIG. 13, or may be coupled to any of the components of the computing device 2400, e.g., be coupled to the memory 2404 and/or to the processing device 2402 of the computing device 2400. In still other embodiments, the RF device 2500 may further include any of the components described with reference to FIG. 14, such as, but not limited to, the battery/power circuit 2414, the memory 2404, and various input and output devices as shown in FIG. 14.

In general, the RF device 2500 may be any device or system that may support wireless transmission and/or reception of signals in the form of electromagnetic waves in the RF range of approximately 3 kiloHertz (kHz) to 300 gigaHertz (GHz). In some embodiments, the RF device 2500 may be used for wireless communications, e.g., in a BS or a UE device of any suitable cellular wireless communications technology, such as GSM, WCDMA, or LTE. In a further example, the RF device 2500 may be used as, or in, e.g., a BS or a UE device of a mm-wave wireless technology such as fifth generation (5G) wireless (i.e., high frequency/short wavelength spectrum, e.g., with frequencies in the range between about 20 and 60 GHz, corresponding to wavelengths in the range between about 5 and 15 millimeters). In yet another example, the RF device 2500 may be used for wireless communications using WiFi technology (e.g., a frequency band of 2.4 GHz, corresponding to a wavelength of about 12 cm, or a frequency band of 5.8 GHz, spectrum, corresponding to a wavelength of about 5 cm), e.g., in a WiFi-enabled device such as a desktop, a laptop, a video game console, a smart phone, a tablet, a smart TV, a digital audio player, a car, a printer, etc. In some implementations, a WiFi-enabled device may, e.g., be a node in a smart system configured to communicate data with other nodes, e.g., a smart sensor. Still in another example, the RF device 2500 may be used for wireless communications using Bluetooth technology (e.g., a frequency band from about 2.4 to about 2.485 GHz, corresponding to a wavelength of about 12 cm). In other embodiments, the RF device 2500 may be used for transmitting and/or receiving RF signals for purposes other than communication, e.g., in an automotive radar system, or in medical applications such as magneto-resonance imaging (MRI).

In various embodiments, the RF device 2500 may be included in frequency division duplexing (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 14 as included in the RF device 2500, but any one or more of these components may be omitted or duplicated, as suitable for the application. For example, in some embodiments, the RF device 2500 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2500 may be an RF device supporting only wireless reception (e.g., an RF receiver), in which case it may include the components of the RX path, but not the components of the TX path; or the RF device 2500 may be an RF device supporting only wireless transmission (e.g., an RF transmitter), in which case it may include the components of the TX path, but not the components of the RX path.

In some embodiments, some or all of the components included in the RF device 2500 may be attached to one or more motherboards. In some embodiments, some or all of these components are fabricated on a single die, e.g., on a single SoC die.

Additionally, in various embodiments, the RF device 2500 may not include one or more of the components illustrated in FIG. 14, but the RF device 2500 may include interface circuitry for coupling to the one or more components. For example, the RF device 2500 may not include an antenna 2502, but may include antenna interface circuitry (e.g., a matching circuitry, a connector and driver circuitry) to which an antenna 2502 may be coupled. In another set of examples, the RF device 2500 may not include a digital processing unit 2508 or a local oscillator 2506, but may include device interface circuitry (e.g., connectors and supporting circuitry) to which a digital processing unit 2508 or a local oscillator 2506 may be coupled.

As shown in FIG. 14, the RF device 2500 may include an antenna 2502, a duplexer 2504, a local oscillator 2506, a digital processing unit 2508. As also shown in FIG. 14, the RF device 2500 may include an RX path which may include an RX path amplifier 2512, an RX path pre-mix filter 2514, a RX path mixer 2516, an RX path post-mix filter 2518, and an analog-to-digital converter (ADC) 2520. As further shown in FIG. 14, the RF device 2500 may include a TX path which may include a TX path amplifier 2522, a TX path post-mix filter 2524, a TX path mixer 2526, a TX path pre-mix filter 2528, and a digital-to-analog converter (DAC) 2530. Still further, the RF device 2500 may further include an impedance tuner 2532 and an RF switch 2534. In various embodiments, the RF device 2500 may include multiple instances of any of the components shown in FIG. 14. The RX path amplifier 2512, the TX path amplifier 2522, the duplexer 2504, and the RF switch 2534 may be considered to form, or be a part of, an RF FE of the RF device 2500. The RX path mixer 2516 and the TX path mixer 2526 (possibly with their associated pre-mix and post-mix filters shown in FIG. 14) may be considered to form, or be a part of, an RF transceiver of the RF device 2500 (or of an RF receiver or an RF transmitter if only RX path or TX path components, respectively, are included in the RF device 2500).

The antenna 2502 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2500 is an FDD transceiver, the antenna 2502 may be configured for concurrent reception and transmission of communication signals in separate, i.e., non-overlapping and non-continuous, bands of frequencies, e.g., in bands having a separation of, e.g., 20 MHz from one another. If the RF device 2500 is a TDD transceiver, the antenna 2502 may be configured for sequential reception and transmission of communication signals in bands of frequencies which may be the same, or overlapping for TX and RX paths. In some embodiments, the RF device 2500 may be a multi-band RF device, in which case the antenna 2502 may be configured for concurrent reception of signals having multiple RF components in separate frequency bands and/or configured for concurrent transmission of signals having multiple RF components in separate frequency bands. In such embodiments, the antenna 2502 may be a single wide-band antenna or a plurality of band-specific antennas (i.e., a plurality of antennas each configured to receive and/or transmit signals in a specific band of frequencies). In various embodiments, the antenna 2502 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2500 may include more than one antenna 2502 to implement antenna diversity. In some such embodiments, the RF switch 2534 may be deployed to switch between different antennas.

An output of the antenna 2502 may be coupled to the input of the duplexer 2504. The duplexer 2504 may be any suitable component configured for filtering multiple signals to allow for bidirectional communication over a single path between the duplexer 2504 and the antenna 2502. The duplexer 2504 may be configured for providing RX signals to the RX path of the RF device 2500 and for receiving TX signals from the TX path of the RF device 2500.

The RF device 2500 may include one or more local oscillators 2506, configured to provide local oscillator signals which may be used for downconversion of the RF signals received by the antenna 2502 and/or upconversion of the signals to be transmitted by the antenna 2502.

The RF device 2500 may include the digital processing unit 2508, which may include one or more processing devices. In some embodiments, the digital processing unit 2508 may be implemented as the processing device 2402 shown in FIG. 13, descriptions of which are provided above (when used as the digital processing unit 2508, the processing device 2402 may, but does not have to, implement any of the IC devices as described herein, e.g., IC devices having at least one nearest-neighboring pair of doped semiconductor regions with a protection liner therebetween in accordance with any of the embodiments disclosed herein). The digital processing unit 2508 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 14, in some embodiments, the RF device 2500 may further include a memory device, e.g., the memory device 2404 as described with reference to FIG. 14, configured to cooperate with the digital processing unit 2508. When used within, or coupled to, the RF device 2500, the memory device 2404 may, but does not have to, implement any of the IC devices as described herein, e.g., IC devices having at least one nearest-neighboring pair of doped semiconductor regions with a protection liner therebetween in accordance with any of the embodiments disclosed herein.

Turning to the details of the RX path that may be included in the RF device 2500, the RX path amplifier 2512 may include an low-noise amplifier (LNA). An input of the RX path amplifier 2512 may be coupled to an antenna port (not shown) of the antenna 2502, e.g., via the duplexer 2504. The RX path amplifier 2512 may amplify the RF signals received by the antenna 2502.

An output of the RX path amplifier 2512 may be coupled to an input of the RX path pre-mix filter 2514, which may be, e.g., a harmonic or band-pass filter, configured to filter received RF signals that have been amplified by the RX path amplifier 2512.

An output of the RX path pre-mix filter 2514 may be coupled to an input of the RX path mixer 2516, also referred to as a downconverter. The RX path mixer 2516 may include two inputs and one output. A first input may be configured to receive the RX signals, which may be current signals, indicative of the signals received by the antenna 2502 (e.g., the first input may receive the output of the RX path pre-mix filter 2514). A second input may be configured to receive local oscillator signals from one of the local oscillators 2506. The RX path mixer 2516 may then mix the signals received at its two inputs to generate a downconverted RX signal, provided at an output of the RX path mixer 2516. As used herein, downconversion refers to a process of mixing a received RF signal with a local oscillator signal to generate a signal of a lower frequency. In particular, the downconverter 2516 may be configured to generate the sum and/or the difference frequency at the output port when two input frequencies are provided at the two input ports. In some embodiments, the RF device 2500 may implement a direct-conversion receiver (DCR), also known as homodyne, synchrodyne, or zero-IF receiver, in which case the RX path mixer 2516 may be configured to demodulate the incoming radio signals using local oscillator signals whose frequency is identical to, or very close to the carrier frequency of the radio signal. In other embodiments, the RF device 2500 may make use of downconversion to an intermediate frequency (IF). IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2516 may include several such stages of IF conversion.

Although a single RX path mixer 2516 is shown in the RX path of FIG. 14, in some embodiments, the RX path mixer 2516 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2502 and an in-phase component of the local oscillator signal provided by the local oscillator 2506. The second RX path mixer may be configured for performing downconversion to generate a quadrature (Q) downconverted RX signal by mixing the RX signal received by the antenna 2502 and a quadrature component of the local oscillator signal provided by the local oscillator 2506 (the quadrature component is a component that is offset in phase from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2516 may, optionally, be coupled to the RX path post-mix filter 2518, which may be low-pass filters. In case the RX path mixer 2516 is a quadrature mixer that implements the first and second mixers as described above, the in-phase and quadrature components provided at the outputs of the first and second mixers respectively may be coupled to respective individual first and second RX path post-mix filters included in the filter 2518.

The ADC 2520 may be configured to convert the mixed RX signals from the RX path mixer 2516 from analog to digital domain. The ADC 2520 may be a quadrature ADC that, similar to the RX path quadrature mixer 2516, may include two ADCs, configured to digitize the downconverted RX path signals separated in in-phase and quadrature components. The output of the ADC 2520 may be provided to the digital processing unit 2508, configured to perform various functions related to digital processing of the RX signals so that information encoded in the RX signals can be extracted.

Turning to the details of the TX path that may be included in the RF device 2500, the digital signal to later be transmitted (TX signal) by the antenna 2502 may be provided, from the digital processing unit 2508, to the DAC 2530. Similar to the ADC 2520, the DAC 2530 may include two DACs, configured to convert, respectively, digital I- and Q-path TX signal components to analog form.

Optionally, the output of the DAC 2530 may be coupled to the TX path pre-mix filter 2528, which may be a low-pass filter (or a pair of filters, in case of quadrature processing) configured to filter out, from the analog TX signals output by the DAC 2530, the signal components outside of the desired band. The digital TX signals may then be provided to the TX path mixer 2526, which may also be referred to as an upconverter. Similar to the RX path mixer 2516, the TX path mixer 2526 may include a pair of TX path mixers, for in-phase and quadrature component mixing. Similar to the first and second RX path mixers that may be included in the RX path, each of the TX path mixers of the TX path mixer 2526 may include two inputs and one output. A first input may receive the TX signal components, converted to the analog form by the respective DAC 2530, which are to be upconverted to generate RF signals to be transmitted. The first TX path mixer may generate an in-phase (I) upconverted signal by mixing the TX signal component converted to analog form by the DAC 2530 with the in-phase component of the TX path local oscillator signal provided from the local oscillator 2506 (in various embodiments, the local oscillator 2506 may include a plurality of different local oscillators, or be configured to provide different local oscillator frequencies for the mixer 2516 in the RX path and the mixer 2526 in the TX path). The second TX path mixer may generate a quadrature phase (Q) upconverted signal by mixing the TX signal component converted to analog form by the DAC 2530 with the quadrature component of the TX path local oscillator signal. The output of the second TX path mixer may be added to the output of the first TX path mixer to create a real RF signal. A second input of each of the TX path mixers may be coupled the local oscillator 2506.

Optionally, the RF device 2500 may include the TX path post-mix filter 2524, configured to filter the output of the TX path mixer 2526.

The TX path amplifier 2522 may be a power amplifier (PA), configured to amplify the upconverted RF signal before providing it to the antenna 2502 for transmission.

In various embodiments, any of the RX path pre-mix filter 2514, the RX path post-mix filter 2518, the TX post-mix filter 2524, and the TX pre-mix filter 2528 may be implemented as RF filters. In some embodiments, each of such RF filters may include one or more, typically a plurality of, resonators (e.g., film bulk acoustic resonators (FBARs), Lamb wave resonators, and/or contour-wave resonators), arranged, e.g., in a ladder configuration. An individual resonator of an RF filter may include a layer of a piezoelectric material such as aluminum nitride (AlN), enclosed between a bottom electrode and a top electrode, with a cavity provided around a portion of each electrode in order to allow a portion of the piezoelectric material to vibrate during operation of the filter. In some embodiments, an RF filter may be implemented as a plurality of RF filters, or a filter bank. A filter bank may include a plurality of RF resonators which may be coupled to a switch, e. g., the RF switch 2534, configured to selectively switch any one of the plurality of RF resonators on and off (i.e., activate any one of the plurality of RF resonators), in order to achieve desired filtering characteristics of the filter bank (i.e., in order to program the filter bank). For example, such a filter bank may be used to switch between different RF frequency ranges when the RF device 2500 is, or is included in, a BS or in a UE device. In another example, such a filter bank may be programmable to suppress TX leakage on the different duplex distances.

The impedance tuner 2532 may include any suitable circuitry, configured to match the input and output impedances of the different RF circuitries to minimize signal losses in the RF device 2500. For example, the impedance tuner 2532 may include an antenna impedance tuner. Being able to tune the impedance of the antenna 2502 may be particularly advantageous because antenna's impedance is a function of the environment that the RF device 2500 is in, e.g. antenna's impedance changes depending on, e.g., if the antenna is held in a hand, placed on a car roof, etc.

As described above, the RF switch 2534 may be used to selectively switch between a plurality of instances of any one of the components shown in FIG. 14, in order to achieve desired behavior and characteristics of the RF device 2500. For example, in some embodiments, an RF switch may be used to switch between different antennas 2502. In other embodiments, an RF switch may be used to switch between a plurality of RF resonators (e.g., by selectively switching RF resonators on and off) of any of the filters included in the RF device 2500.

In various embodiments, IC devices including one or more nearest-neighboring pairs of doped semiconductor regions with a protection liner therebetween as described herein may be particularly advantageous when used in any of the duplexer 2504, RX path amplifier 2512, RX path pre-mix filter 2514, RX path post-mix filter 2518, TX path amplifier 2522, TX path pre-mix filter 2528, TX path post-mix filter 2524, impedance tuner 2532, and/or RF switch 2534.

The RF device 2500 provides a simplified version and, in further embodiments, other components not specifically shown in FIG. 14 may be included. For example, the RX path of the RF device 2500 may include a current-to-voltage amplifier between the RX path mixer 2516 and the ADC 2520, which may be configured to amplify and convert the downconverted signals to voltage signals. In another example, the RX path of the RF device 2500 may include a balun transformer for generating balanced signals. In yet another example, the RF device 2500 may further include a clock generator, which may, e.g., include a suitable phase-locked loop (PLL), configured to receive a reference clock signal and use it to generate a different clock signal which may then be used for timing the operation of the ADC 2520, the DAC 2530, and/or which may also be used by the local oscillator 2506 to generate the local oscillator signals to be used in the RX path or the TX path.

The following paragraphs provide various examples of the embodiments disclosed herein.

Example 1 provides an integrated circuit (IC) device, including a channel material (e.g., the channel material 202) having a first face and a second face opposite the first face; a first doped semiconductor region (e.g., the doped semiconductor region 205b) and a second doped semiconductor region (e.g., the doped semiconductor region 205c) in the channel material, where at least one of the first doped semiconductor region or the second doped semiconductor region extends from the second face of the channel material towards the first face of the channel material by a first distance from the second face of the channel material; an insulator structure (e.g., the insulator structure 810) in a portion of the channel material between the first doped region and the second doped region, the insulator structure extending from the second face of the channel material towards the first face of the channel material by a second distance from the second face of the channel material, the second distance being greater than the first distance, where the insulator structure has a first portion (e.g., the first portion 810-1) and a second portion (e.g., the second portion 810-2), the first portion is a portion of the insulator structure extending from the second face of the channel material to the first distance, the second portion is a portion of the insulator structure extending from the first distance from the second face of the channel material to the second distance from the second face of the channel material, and the insulator structure includes a liner material (e.g., the liner material 212) that is present on at least portions of sidewalls of the insulator structure in the first portion but absent on at least portions of the sidewalls of the insulator structure in the second portion.

Example 2 provides the IC device according to example 1, where the second distance is substantially equal to a distance between the first face and the second face (i.e., the insulator structure extends through the entire thickness of the channel material).

Example 3 provides the IC device according to examples 1 or 2, where the insulator structure further includes an insulator material (e.g., the insulator material 214), on a portion of a sidewall of the insulator structure that is closest to the first doped region, the liner material is between the insulator material and the first doped region, and on a portion of a sidewall of the insulator structure that is closest to the second doped region, the liner material is between the insulator material and the second doped region.

Example 4 provides the IC device according to example 3, where on the portion of the sidewall of the insulator structure that is closest to the first doped region, the liner material is in contact with the first doped region.

Example 5 provides the IC device according to example 4, where on the portion of the sidewall of the insulator structure that is closest to the second doped region, the liner material is in contact with the second doped region.

Example 6 provides the IC device according to any one of examples 3-5, where the insulator material in at least a portion of the second portion of the insulator structure is in contact with the channel material.

Example 7 provides the IC device according to example 6, where a width (i.e., a dimension measured in a direction substantially parallel to a support over which the IC device is provided, the support being, e.g., a die, a wafer, a substrate, a package substrate, or a carrier substrate, e.g., a dimension along the y-axis of the coordinate system shown in the present drawings) of a sub-portion of the second portion of the insulator structure is smaller than a width of another sub-portion of the second portion of the insulator structure.

Example 8 provides the IC device according to any one of examples 1-7, where an average width of the first portion of the insulator structure is greater than an average width of the second portion of the insulator structure.

Example 9 provides the IC device according to any one of examples 1-8, where the liner material has a thickness between about 0.5 and 2.5 nanometers (e.g., between about 1 and 2 nm or about 1.5 nm).

Example 10 provides the IC device according to any one of examples 1-9, where the liner material is etch-selective with respect to the channel material.

Example 11 provides the IC device according to any one of examples 1-10, where the liner material includes oxygen.

Example 12 provides the IC device according to any one of examples 1-11, where the channel material has a shape of a fin.

Example 13 provides the IC device according to any one of examples 1-12, further including a first transistor (e.g., 208) and a second transistor (e.g., 209) (adjacent to the first transistor), where the first doped semiconductor region is a source region or a drain region of the first transistor, and the second doped semiconductor region is a source region or a drain region of the second transistor.

Example 14 provides the IC device according to any one of examples 1-13, further including a third doped region and a fourth doped region in the channel material, where the first, second, third, and fourth doped regions are spaced apart from each other, the first and second doped regions are a nearest-neighbor pair of doped regions, and at least a portion of the channel material channel material has a shape of a fin.

Example 15 provides the IC device according to any one of examples 1-14, where the liner material is absent on all portions of the sidewalls of the insulator structure in the second portion.

Example 16 provides an integrated circuit (IC) device, including a semiconductor material having a first face and a second face opposite the first face; and an insulator structure comprising a protection material and an insulator material, the insulator structure extending from the second face towards the first face, wherein a first portion of the insulator structure extends from the second face to a first distance and includes the protection material between the insulator material and the semiconductor material, a second portion of the insulator structure extends from the first distance to a second distance from the second face, the second distance being greater than the first distance, and in at least a part of the second portion, the insulator material is in contact with the semiconductor material.

Example 17 provides the IC device according to example 16, where the protection material has a thickness between about 0.5 and 2.5 nanometers (e.g., between about 1 and 2 nanometers or about 1.5 nanometers).

Example 18 provides the IC device according to any one of examples 16-17, where the protection material includes at least one of aluminum and oxygen, or hafnium and oxygen.

Example 19 provides the IC device according to any one of examples 16-18, further including a first doped semiconductor region (e.g., the doped semiconductor region 205b) and a second doped semiconductor region (e.g., the doped semiconductor region 205c) at least partially in the semiconductor material, extending from the second face of the semiconductor material towards the first face of the semiconductor material by the first distance or less.

Example 20 provides the IC device according to any one of examples 16-19, where on a portion of a sidewall of the insulator structure that is closest to the first doped region, the protection material is between the insulator material and the first doped region, and on a portion of a sidewall of the insulator structure that is closest to the second doped region, the protection material is between the insulator material and the second doped region.

Example 21 provides the IC device according to any one of examples 16-20, where the semiconductor material is a first semiconductor material, and the IC device further including one or more nanoribbons extending, along an axis about parallel to the first face, between the first doped semiconductor region and the second doped semiconductor region, the one or more nanoribbons including a second semiconductor material (e.g., the same as or different than the first semiconductor material).

Example 22 provides a method of fabricating an integrated circuit (IC) structure, the method including providing a channel material; providing a first doped semiconductor region and a second doped semiconductor region in the channel material; removing a portion of the channel material to create an opening between the first doped semiconductor region and the second doped semiconductor region; depositing a protection material along sidewalls and a bottom of the opening; after depositing the protection material, extending the opening beyond the protection material to form an extended opening; and at least partially filling the extended opening with an insulator material.

Example 23 provides the method according to example 21, further including before extending the opening, removing a portion of the protection material at the bottom of the opening to expose a portion of the channel material.

Example 24 provides the IC device according to any one of the preceding examples, where the IC device includes or is a part of a central processing unit.

Example 25 provides the IC device according to any one of the preceding examples, where the IC device includes or is a part of a memory device.

Example 26 provides the IC device according to any one of the preceding examples, where the IC device further includes a plurality of memory cells, each of the memory cells including a storage element.

Example 27 provides the IC device according to example 26, where the storage element is one of a capacitor, a magnetoresistive material, a ferroelectric material, or a resistance-changing material.

Example 28 provides the IC device according to any one of the preceding examples, where the IC device includes or is a part of a logic circuit.

Example 29 provides the IC device according to any one of the preceding examples, where the IC device includes or is a part of input/output circuitry.

Example 30 provides the IC device according to any one of the preceding examples, where the IC device includes or is a part of a field programmable gate array transceiver.

Example 31 provides the IC device according to any one of the preceding examples, where the IC device includes or is a part of a field programmable gate array logic.

Example 32 provides the IC device according to any one of the preceding examples, where the IC device includes or is a part of a power delivery circuitry.

Example 33 provides the IC device according to any one of the preceding examples, where the IC device includes or is a part of a III-V amplifier.

Example 34 provides the IC device according to any one of the preceding examples, where the IC device includes or is a part of Peripheral Component Interconnect Express circuitry or Double Data Rate transfer circuitry.

Example 35 provides an IC package that includes a die including an IC device according to any one of the preceding examples; and a further IC component, coupled to the die.

Example 36 provides the IC package according to example 35, where the further IC component includes one of a package substrate, an interposer, or a further IC support structure.

Example 37 provides a computing device that includes a carrier substrate and an IC device, coupled to the carrier substrate, where the IC device is an IC device according to any one of the preceding examples, or the IC device is included in the IC package according to any one of examples 35-36.

Example 38 provides the computing device according to example 37, where the computing device is a wearable or handheld computing device.

Example 39 provides the computing device according to examples 37 or 38, where the computing device further includes one or more communication chips and an antenna.

Example 40 provides the computing device according to any one of examples 37-39, where the carrier substrate is a motherboard.

Example 41 provides a method of manufacturing an IC device, the method including providing the IC device according to any one of the preceding examples.

1. An integrated circuit (IC) device, comprising:
a channel material having a first face and a second face opposite the first face;
a first doped region and a second doped region in the channel material, extending from the second face towards the first face by a first distance; and
an insulator structure in a portion of the channel material between the first doped region and the second doped region, the insulator structure extending from the second face towards the first face by a second distance, the second distance being greater than the first distance, wherein:
the insulator structure has a first portion and a second portion,
the first portion is a portion of the insulator structure extending from the second face to the first distance,
the second portion is a portion of the insulator structure extending from the first distance to the second distance, and
the insulator structure includes a liner material that is present on at least portions of sidewalls of the insulator structure in the first portion but absent on at least portions of the sidewalls of the insulator structure in the second portion.

2. The IC device according to claim 1, wherein the second distance is substantially equal to a distance between the first face and the second face.

3. The IC device according to claim 1, wherein:
the insulator structure further includes an insulator material,
on a portion of a sidewall of the insulator structure that is closest to the first doped region, the liner material is between the insulator material and the first doped region, and
on a portion of a sidewall of the insulator structure that is closest to the second doped region, the liner material is between the insulator material and the second doped region.

4. The IC device according to claim 3, wherein:
on the portion of the sidewall of the insulator structure that is closest to the first doped region, the liner material is in contact with the first doped region.

5. The IC device according to claim 3, wherein the insulator material in at least a portion of the second portion of the insulator structure is in contact with the channel material.

6. The IC device according to claim 1, wherein a width of a sub-portion of the second portion of the insulator structure is smaller than a width of another sub-portion of the second portion of the insulator structure.

7. The IC device according to claim 1, wherein an average width of the first portion of the insulator structure is greater than an average width of the second portion of the insulator structure.

8. The IC device according to claim 1, wherein the liner material has a thickness between about 0.5 and 2.5 nanometers.

9. The IC device according to claim 1, wherein the liner material includes oxygen.

10. The IC device according to claim 1, wherein the channel material has a shape of a fin.

11. The IC device according to claim 1, further comprising:
a first transistor and a second transistor,
wherein:
the first doped region is a source region or a drain region of the first transistor, and
the second doped region is a source region or a drain region of the second transistor.

12. The IC device according to claim 1, further comprising:
a third doped region and a fourth doped region in the channel material,
wherein:
the first, second, third, and fourth doped regions are spaced apart from each other,
the first and second doped regions are a nearest-neighbor pair of doped regions, and
at least a portion of the channel material has a shape of a fin.

13. The IC device according to claim 1, wherein the liner material is absent on all portions of the sidewalls of the insulator structure in the second portion.

14. An integrated circuit (IC) device, comprising:
a semiconductor material having a first face and a second face opposite the first face; and
an insulator structure comprising a protection material and an insulator material, the insulator structure extending from the second face towards the first face,
wherein:
a first portion of the insulator structure extends from the second face to a first distance and includes the protection material between the insulator material and the semiconductor material,
a second portion of the insulator structure extends from the first distance to a second distance from the second face, the second distance being greater than the first distance, and
in at least a part of the second portion, the insulator material is in contact with the semiconductor material.

15. The IC device according to claim 14, wherein the protection material has a thickness between about 0.5 and 2.5 nanometers.

16. The IC device according to claim 14, further comprising:
a first doped region and a second doped region in the semiconductor material, extending from the second face towards the first face by the first distance or less.

17. The IC device according to claim 16, wherein:
on a portion of a sidewall of the insulator structure that is closest to the first doped region, the protection material is between the insulator material and the first doped region, and
on a portion of a sidewall of the insulator structure that is closest to the second doped region, the protection material is between the insulator material and the second doped region.

18. The IC device according to claim 16, wherein:
the semiconductor material is a first semiconductor material, and
the IC device further includes one or more nanoribbons extending between the first doped region and the second doped region, the one or more nanoribbons comprising a second semiconductor material.

19. A method of fabricating an integrated circuit (IC) structure, the method comprising:
providing a channel material, wherein the channel material includes a first face and a second face, the second face opposite the first face;
providing a first doped region and a second doped region in the channel material, wherein the first doped region and the second doped region extend into a portion of the channel material from the second face to a first distance;
removing a portion of the channel material to create an opening between the first doped region and the second doped region;
depositing a protection material along sidewalls and a bottom of the opening;
after depositing the protection material, extending the opening beyond the protection material to form an extended opening; and
at least partially filling the extended opening with an insulator material.

20. The method according to claim 19, further comprising:
before extending the opening, removing a portion of the protection material at the bottom of the opening to expose a portion of the channel material.
